(19) United States
(12) Patent Application Publication
(10) Pub. No.: US 2009/0129166 A1
(43) Pub. Date: May 21, 2009

(54) METHOD, CIRCUIT AND SYSTEM FOR SENSING A CELL IN A NON-VOLATILE MEMORY ARRAY

(76) Inventors: Eduardo Maayan, Kfar Saba (IL); Ilan Bloom, Haifa (IL)

Correspondence Address: EMPK & Shiloh, LLP;c/o Landon IP, Inc., 1700 Diagonal Road, Suite 450, Alexandria, VA, 22314, US

(21) Appl. No.: 11/940,352

(22) Filed: Nov. 15, 2007

(51) Int. Cl. G11C 16/06

(52) U.S. Cl. 365/185.18

(57) ABSTRACT

Disclosed is a method, circuit and system for evaluating the status of a data storage area in a non-volatile memory cell within a non-volatile memory cell array. According to some embodiments of the present invention, leakage current in at least one other cell in proximity with the cell being evaluated is suppressed. Leakage current suppression may be achieved by applying a suppression voltage to the word of the cell(s) whose leakage current(s) are to be suppressed.

### FIELD OF THE DISCLOSURE

This disclosure relates generally to the field of semiconductors. More particularly, this disclosure relates to a method, circuit and system for sensing a nonvolatile memory (“NVM”) cell in an NVM array.

### BACKGROUND

Non-volatile memory (“NVM”) cells are fabricated in a variety of structures, including but not limited to Poly-silicon floating gate structures, as shown in FIG. 1A, and Nitride Read Only Memory (“NROM”) structures, as shown in FIGS. 1B and 1C. As is well known, an NVM cell's logical state may be defined and/or correlated to the cell's Threshold Voltage (“Vₜ”), where Vₜ is usually defined as the gate to source voltage at which the cell begins to significantly conduct current through its channel. According to some NVM cell structures where the charge storage layer is composed of a conductive material (for example, polysilicon), such as the cell shown in FIG. 1A, each cell may include only one charge storage region and may thus be associated with only one Vₜ value at any given instance. Other cell structures, such as the one exemplified by the NROM cell in FIG. 1B, may include one, two or more charge storage regions within a non-conducting charge storage region of the cell, and thus may have one, two or more independent Vₜ values associated with the cell at a given instance.

The fabrication and operation of a multi-charge-storage-region NVM cell is well known. For purposes of this disclosure, the terms: (1) “NVM cell”, (2) “Vₜ” (3) and/or any other term associated with an NVM cell, may be applicable either to a single charge-storage-region NVM cell or to each charge storage region of a multi-charge-storage-region NVM cell.

An NVM cell's Vt, and thus its logical state, is in part correlated to the amount of charge stored in the NVM cell's charge storage region. The amount of charge stored in a cell's charge storage region may be regulated in order to alter the cell's logical state Generally, an NVM cell's Vt may be increased by applying to the cell one or more programming pulses adapted to inject charge into the cell's charge storage region. Conversely, the cell's Vt may be decreased by applying one or more erase pulses adapted to force charge out of the cell's charge storage region or to inject opposite type of charge into the cell's charge storage region.

FIG. 2A shows a voltage distribution graph depicting possible threshold voltage distributions of a binary non-volatile memory cell. For example, cells having a Vt lower than Erase Verify (“EV”) level are considered to be erase verified, and cells having a Vt higher than Program Verify (“PV”) level are considered to be program verified.

Also visible in FIG. 2A is a vertical line designating a Read Verify level (RV), in between the EV and the PV level. According to the RV level, the cell's state is determined, which state is either programmed or erased. In order to read a binary cell having only two possible logical states (for example, 0 or 1), the cell's Vt is typically compared to the Vt of a read reference cell whose Vt is known to be at or near the given RV level. The comparison may be performed directly or indirectly. For example, the comparison may be performed by current or voltage signals that are relative to the cells Vt, other comparison methods may also be applied. The difference between a cell's PV and RV levels, is typically referred to as the “programming margin”, and the difference between a cell's RV and EV levels, is typically referred to as the “erase margin”.

In order to correctly read the programmed and erased bits of a cell, the reference read level should be determined and set such that it would provide adequate margin from the programmed storage area having the lowest Vt, and with adequate margin from the erased storage area having the highest Vt. Those margins are required to overcome circuit and sensing scheme deficiencies, environmental effects, charge loss or charge redistribution in the storage area, and so on. The larger the margins, the better the distinguishing between the erased and programmed states of the cell involved.

FIG. 2B shows a voltage distribution graph depicting possible voltage threshold distributions in the charge storage region of a multi-level non-volatile memory cell (“MLC”), wherein one set of vertical lines depict boundary values correlated with each of the cell's possible Program Verify Threshold Voltages (PV00, PV01 and so on) and another set of vertical lines depict boundary values correlated with the Read Verify levels of each of the cell's possible Program states (RV00, RV01, and so on). As opposed to binary cells where each charge storage region is able to store only one bit (for example, 0 or 1), MLC cells may store two or more bits per charge storage region (for example, 00, 01, 11 and 10) by partitioning the full range of possible Vt values associated with a given charge storage regions into a multiplicity of sub-ranges, wherein each sub-range is associated with a separate logical state, as depicted in FIG. 2B.

While an NVM cell's Vt may be evaluated as part of a read operation, in order to determine the cell's logical state, its Vt may also be evaluated between program and/or erase pulses during programming and/or erasing operations Generally, in order to determine an NVM cell's Vt (for example, logical state—erased, programmed, or programmed at one of multiple possible program states within a multi-level cell (“MLC”)), the cell's Vt level is compared to that of one or more reference cells or structures each of whose threshold voltage levels is at a known voltage level. Comparing the threshold voltage of an NVM cell to that of a reference cell is often accomplished by generating current or voltage signals which are relative to the cells Vt and then performing these signals comparison using a sense amplifier Various techniques for comparing an NVM's threshold voltage against those of one or more reference cells are well known and will be further described below.

In producing mass data storage devices, NVM cells are usually fabricated as part of a large matrix of cells. Depending upon which one of the many known architectures and operating methodologies is used, each cell may be addressable, programmable, readable and/or erasable either individually or as part of a group/block of cells. Most cell array architectures, including virtual ground arrays, which are well known in the field, include the feature of a multiplicity of repeating segments formed into rows and columns. Each array segment may include a cell area formed of four segmented cell bit lines, an even select area, and an odd select area. The even select area may be located at one end of the cell area and may include a segmented even contact bit line and two select transistors connecting the even contact bit line with the even cell bit lines of the segment. The odd select area may be located at the opposite end of the cell area and may include a segmented odd contact bit line and two select transistors connecting the odd contact bit line with the odd cell bit lines of the segment. The array additionally may include one even contact connected to the even contact bit lines of two neighboring even select areas, one odd contact connected to the odd contact bit lines of two neighboring odd select areas and alternating even and odd metal lines connecting to the even and odd contacts, respectively.

When reading the status (for example, Vₜ) of an NVM cell within an array, the cell may be accessed and activated through word-line and bit line select circuitry associated with the array. FIG. 3A shows an exemplary array segment and a circuit for reading the status of an NVM cell in the shown array segment. The status of exemplary cell 801 in NVM cell array 802 (only a portion thereof is shown) may be read by (1) selecting cell 801 and reference cell 803, and (2) applying appropriate voltages (for example, Drain voltages through global bit lines 807 and 808, and Gate voltages through word lines 805 and 806), that cause a current, Icell, to flow through cell 801, and a current, Iref, to flow through reference 803 The currents Icell and Iref generate voltages Vcell and Vref on nodes 810 and 811, respectively. Vref is in this configuration the read reference signal against which Vcell is compared by sense amplifier 804. If nodes 810 and 811 were forced to ground level (or close to ground level) until time tsen and afterwards these nodes were left floating, then the voltage on nodes 810 and 811 would rise with time from ground (or close to ground level) based on the currents Icell and Iref and on the capacitance of those nodes.

After the ‘sense time’ (tₗₐₜ−tₛₑₙ) lapses, a corresponding signal (lₐₜ) may cause amplifier 804 to output a data relating to the read status of cell 801. If Vcell is greater than Vref, then cell 801 may be determined to be at an erased status (‘1’). If, however, Vcell is smaller than Vref, then cell 801 is at programmed status (‘0’), as demonstrated in diagram 809 (FIG. 3B).

This sensing scheme is known as a “close to ground AC sensing scheme” Other sensing schemes such as “drain side sensing”, “DC sensing”, and like are known to one skilled in the art.

The following U.S. patents describe system, methods and circuits for sensing, and are hereby incorporated by reference in their entirety: (1) U.S. Pat. No. 7,142,464, (2) U.S. Pat. No. 7,095,655; (3) U.S. Pat. No. 6,885,585; (4) U.S. Pat. No. 6,535,434; (5) U.S. Pat. No. 6,233,180; (6) U.S. Pat. No. 6,128,226.

Turning now to FIG. 4A, there is shown a diagram of an exemplary Non-Volatile Memory sensing circuit according to some embodiments, including dashed lines indicating a sensing current path through the cell being sensed. FIG. 4A also shows the ancillary circuitry (X-Decoder, Y-Decoder and Y-MUX) required to access a specific cell and to induce/channel current flow through the selected cell and to a sensing circuit as shown in FIG. 3A. The accessing, operating and sensing of NVM cells with various array structures is well known to one of ordinary skill in the art.

As visible from FIG. 4A, a sensing current associated with an NVM cell being sensed or evaluated usually flows through a current path (for example, bit lines) to which multiple other NVM cells may be connected Turning now to FIG. 4B, three cells below and connected to the same bit-lines as the NVM cell being evaluated are clearly marked with a rectangle. Leakage current, a well known phenomenon with NVM cells, through any of the one or more of these cells connected to the same bit-line, may corrupt the sensing, as visible from FIG. 5. Leakage current from cells located below the cell being evaluated may corrupt (for example, contribute current or reduce current) the sensing current signal produced by the cell being sensed/evaluated (for example, the active cell). As seen from FIG. 5, in the event that any of the cells below the “Active Cell” being sensed produce a leakage current, that leakage current will add to the “Active Cell Current” to produce a “Total Current”, which “Total Current” may not accurately represent the current state of the “Active Cell” whose charge storage region is being evaluated. As a result of the possible increase in Total Current, a mis-read of the cell's state may occur.

If the “active cell” was in the process of being erased, then a false decision may be reached that the cell is in an erased state not because it was sufficiently erased but, rather, because of the current leakage induced by the leaking cells.

If in another case the “active cell” was in the process of being programmed, then the extra current (due to leaky cells) may cause the “active cell” to appear less programmed than it really is. In such case, additional programming pulses may be applied to the “active cell”, resulting in unnecessary over-programming of the “active cell” (which may affect its endurance and/or reliability), or in an extreme case it may even cause the programming operation to fail (for example, if the overall leakage current of the adjacent cells is higher than the target current of a programmed cell).

A common trigger for the failure or problem described hereinabove is the leakage of cells sharing the “active cell” bit lines while the active cell is being “Read”.

Leakage currents from a cell may be the result of over-erasing or one of many other processes which may cause the cell's Vₜ to be low enough for the cell to conduct current even when it was not expected to do so (for example, when its gate terminal is grounded).

There is a need in the field for an improved method, circuit and system for sensing NVM cells. More specifically, there is a need for method, circuit and system to mitigate the impact of leakage currents on the sensing of an NVM cell.

### SUMMARY OF THE DISCLOSURE

According to some embodiments of the present invention, there is provided a method of evaluating the status of a data storage area in a Non-Volatile Memory (“NVM”) cell within a non-volatile memory array including suppressing leakage current(s) in one or more NVM cells of the array other than the cell being evaluated. As part of suppressing leakage currents, a suppression voltage may be applied to a word-line of the one or more NVM cells whose leakage current is to be suppressed.

According to some embodiments of the present invention, the suppression voltage may be applied to cells sharing a bit line with the cell being evaluated. The suppression voltage is a negative voltage and/or any other voltage adapted to produce a sufficiently strong electric field in an NVM cell to substantially deplete charge carriers from a channel of the NVM cell.

According to some embodiments, there may be provided a circuit for evaluating the status of a data storage area in a Non-Volatile Memory (“NVM”) Cell within a non-volatile memory array. The circuit may include a controller or control circuit adapted to cause a suppression voltage to be applied to one or more NVM cells in proximity to the NVM cell whose data storage area is being evaluated. The circuit may also include a charge pump adapted to produce or generate a suppression voltage. The charge pump may be adapted to produce a suppression voltage capable of inducing a sufficiently strong electric field in a NVM cell to substantially deplete charge carriers from a channel of the NVM cell.

According to further embodiments, the circuit may include a word-line select circuit, wherein the word-line select circuit may be adapted to direct a suppression voltage to a word-line of a NVM cells whose leakage current is to be suppressed.

According to some embodiments, the term ‘evaluating the status of a data storage area in a cell’ may mean: verifying the status of the cell after performing PAE (‘programming after erasing’), reading the data storage area current status, verifying the data storage area ‘Program’ state, or verifying the data storage area ‘Erase’ state According to some embodiments, the NVM cell array may be associated with a ‘virtual-ground’ (“VG”) architecture, a full VG array, sliced VG array, and/or with segmented VG architecture.

As part of the present disclosure, there may be provided a system for evaluating the status of a non-volatile memory (“NVM”) cell of interest that resides within an NVM cell array. According to some embodiments of the present disclosure, the system may comprise an ‘X’ address decoder (“X-DEC”) for driving a word line in the NVM cell array to select a cell of interest and for deactivating other word lines for deselecting other cells, The system may also comprise ‘Y’ address decoder (“Y-DEC”) for activating, when appropriate, selection gates in the NVM cell array to connect, or disconnect, the cell of interest to, or from, corresponding bit lines. The bit lines may be driven (for example, activated and deactivated) by a Y-multiplexer (“Y-MUX”) interoperating with the Y-DEC.

Leakage current in one or more cells that are connected to the bit line(s) of the cell of interest may be suppressed by causing the X-DEC to direct a suppressing voltage while the status of the data storage area is being evaluated. The NVM cell array may be structured as ‘two-bit-per-cell’ architecture. In this architecture, bit lines associated with an ‘evaluated’ data storage area may change roles to allow evaluating both data storage areas (for example, bits).

### BRIEF DESCRIPTION OF THE DRAWINGS

Aspects of this disclosure may best be understood by reference to the following detailed description when read with the accompanying drawings, in which:

FIG. 1A shows a symbolic diagram of a floating gate Non-Volatile Memory cell;

FIG. 1B shows a symbolic diagram of a Nitride Read Only Memory cell;

FIG. 1C shows a symbolic diagram of a Nitride Read Only Memory cell;

FIG. 2A shows a threshold voltage distribution graph of an exemplary threshold voltage distribution, and exemplary associated logical states, within a binary Non-Volatile Memory cell;

FIG. 2B shows a threshold voltage distribution graph of an exemplary threshold voltage distribution, and exemplary associated logical states, within a Multi-Level Non-Volatile Memory cell;

FIG. 3A shows a diagram of a segment of an exemplary Non-Volatile Memory sensing circuit according to some embodiments of the present invention;

FIG. 3B shows a voltage over time diagram of array cells and reference cells to be input to the sensing circuit according to some embodiments of the present invention;

FIG. 4A shows a diagram of an exemplary Non-Volatile Memory sensing circuit according to some embodiments of the present invention, including dashed lines indicating a sensing current path through the cell being sensed;

FIG. 4B shows a diagram of an exemplary Non-Volatile Memory sensing circuit according to some embodiments of the present invention, including dashed lines indicating a sensing current path through the cell being sensed and a rectangular indicator of cells whose leakage current corrupts the sensing current;

FIG. 5 shows a close-up of the sensing and leakage current paths within the circuit shown in FIG. 4B;

FIG. 6 shows a diagram of an exemplary Non-Volatile Memory sensing circuit according to some embodiments of the present invention, including dashed lines indicating a sensing current path and further including an indication of a suppression voltage being applied to the word-lines of cells whose leakage current may corrupt the sensing current;

FIG. 7 shows a close-up of the sensing and leakage current paths within the circuit shown in FIG. 6;

FIG. 8 shows a block diagram of an exemplary Non-Volatile Memory circuit and device according to some embodiments of the present invention;

FIG. 9 shows a flow chart including the steps of an exemplary method of sensing a Non-Volatile Memory cell according to some embodiments of the present invention.

FIG. 10 shows the measured drain current (IDS) vs. the Drain voltage (VDS) characteristics of a leaky NVM cell for different Gate (for example, Word Line) voltages (V_WL).

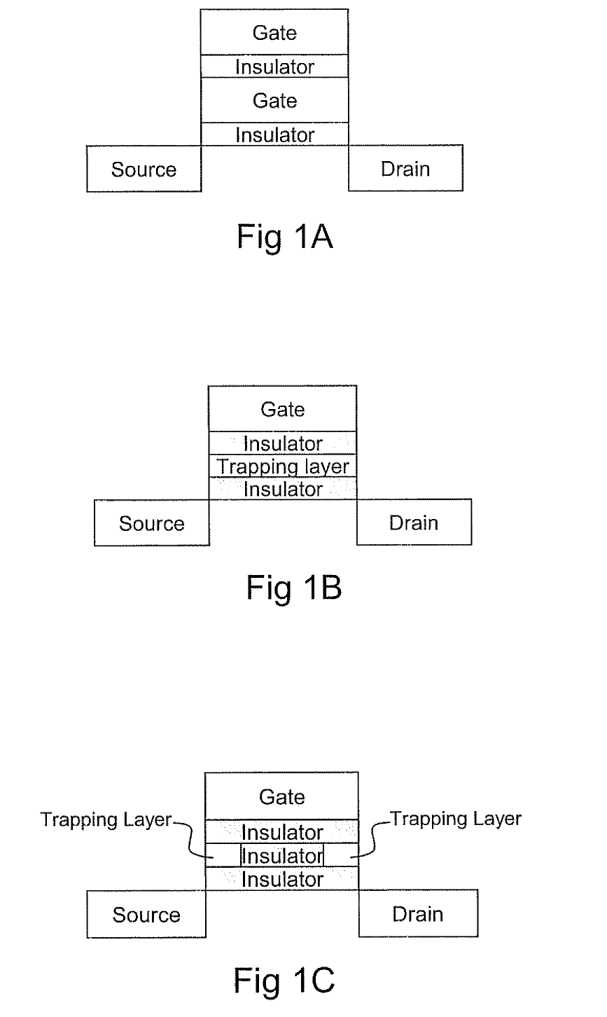

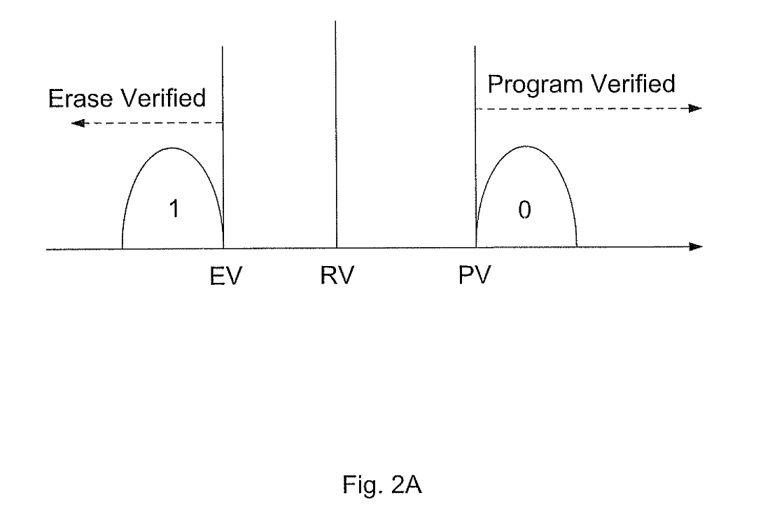

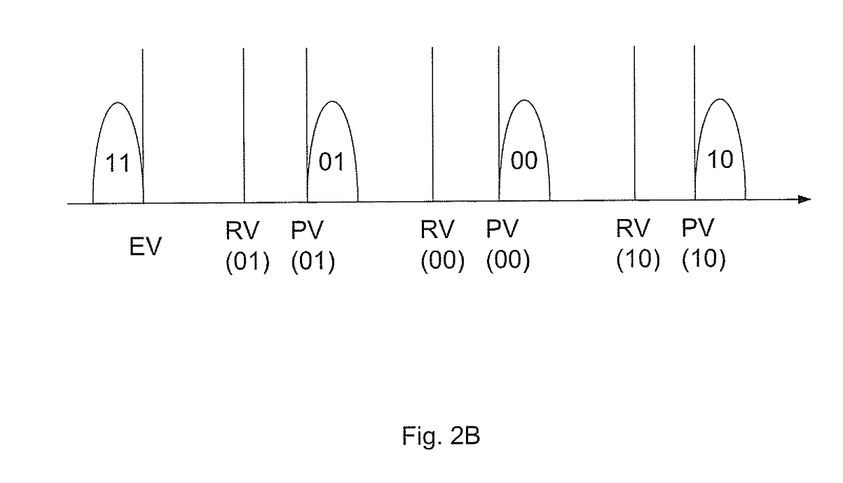

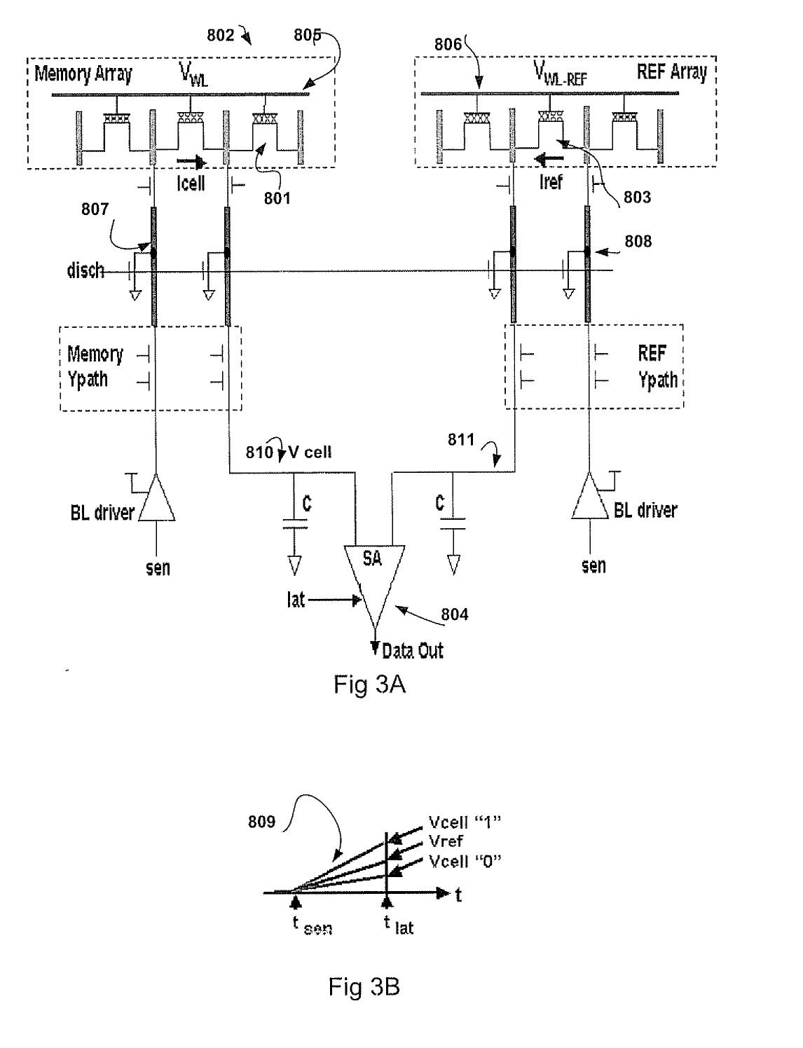

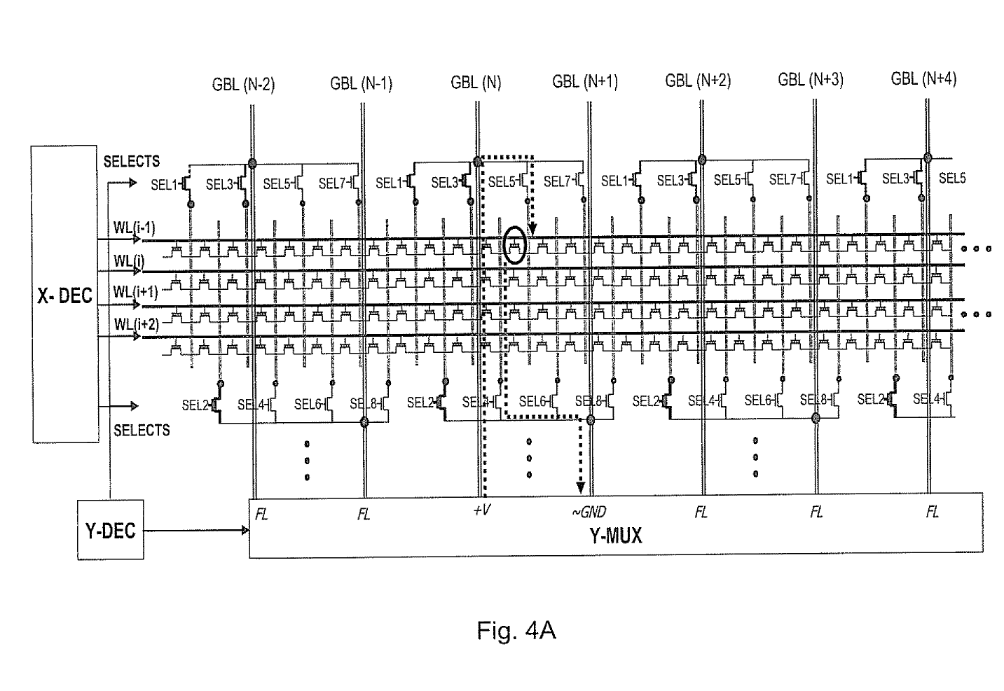

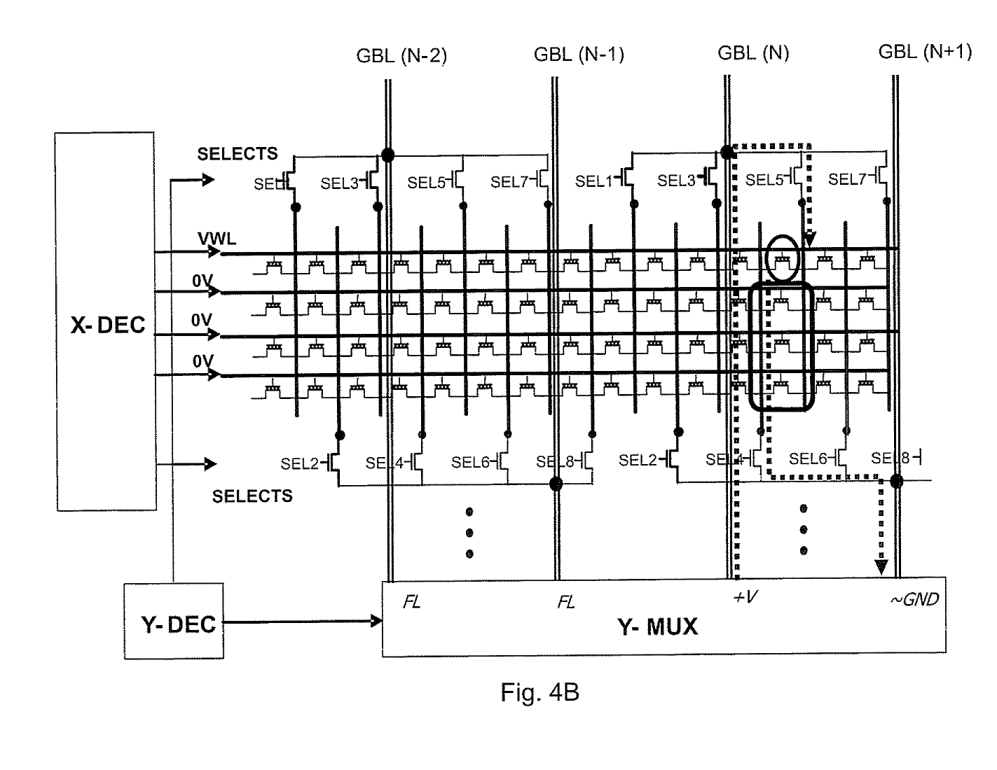

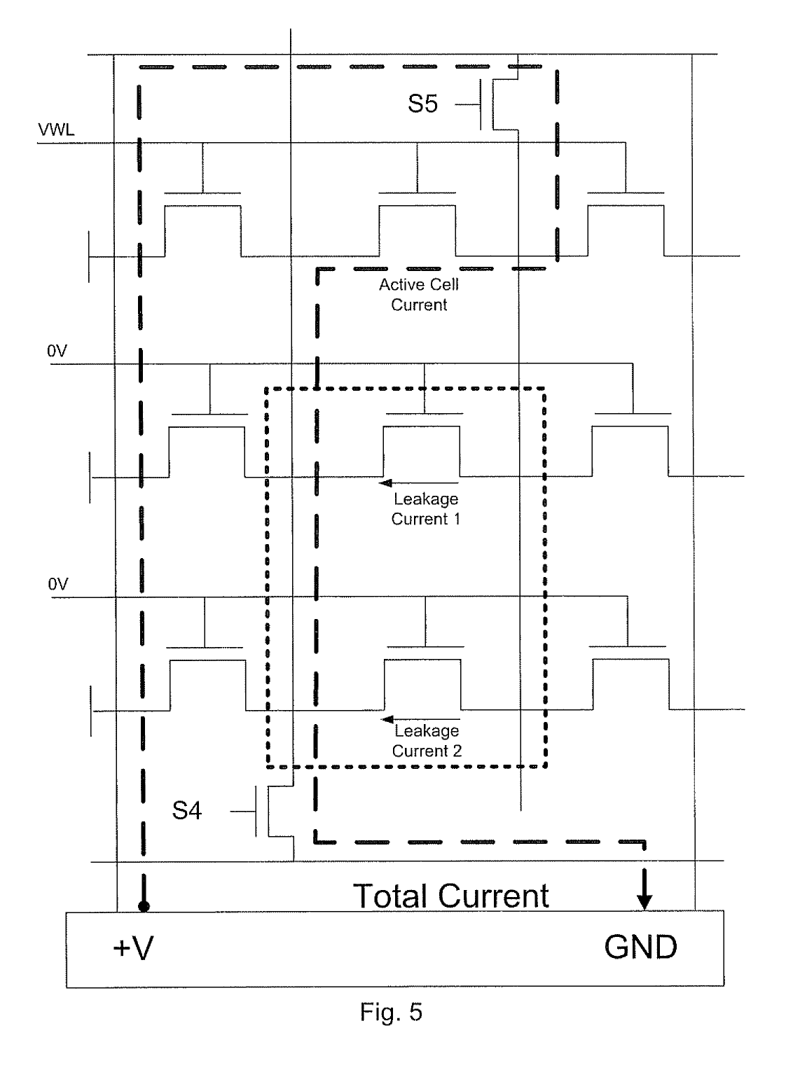

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding. However, it will be understood by those skilled in the art that this may be practiced without these specific details. In other instances, well-known methods, procedures, components and circuits have not been described in detail so as not to obscure this.

Unless specifically stated otherwise, as apparent from the following discussions, it is appreciated that throughout the specification discussions utilizing terms such as “processing”, “computing”, “calculating”, “determining”, or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments may include apparatuses for performing the operations herein. This apparatus may be specially constructed for the desired purposes, or it may comprise a general purpose computer selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs) electrically programmable read-only memories (EPROMs), electrically erasable and programmable read only memories (EEPROMs), magnetic or optical cards, or any other type of media suitable for storing electronic instructions, and capable of being coupled to a computer system bus.

The processes and displays presented herein are not inherently related to any particular computer or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the inventions as described herein.

According to some embodiments, there is provided a method of evaluating the status of a data storage area in a Non-Volatile Memory (“NVM”) cell within a non-volatile memory array including suppressing leakage current(s) in one or more NVM cells of the array other than the cell being evaluated. As part of suppressing leakage currents, a suppression voltage may be applied to a word-line of the one or more NVM cells whose leakage current is to be suppressed.

According to some embodiments, the suppression voltage may be applied to cells sharing a bit line with the cell being evaluated. The suppression voltage is a negative voltage and/or any other voltage adapted to produce a sufficiently strong electric field in a NVM cell to substantially deplete charge carriers from a channel of the NVM cell.

According to some embodiments, there may be provided a circuit for evaluating the status of a data storage area in a Non-Volatile Memory (“NVM”) Cell within a non-volatile memory array. The circuit may include a controller or control circuit adapted to cause a suppression voltage to be applied to one or more NVM cells in proximity to the NVM cell whose data storage area is being evaluated. The circuit may also include a charge pump adapted to produce or generate a suppression voltage. The charge pump may be adapted to produce a suppression voltage capable of inducing a sufficiently strong electric field in an NVM cell to substantially deplete charge carriers from a channel of the NVM cell.

According to further embodiments of the present invention, the circuit may include a word-line select circuit, wherein the word-line select circuit may be adapted to direct a suppression voltage to a word-line of a NVM cells whose leakage current is to be suppressed.

According to some embodiments of the present invention, the term ‘evaluating the status of a data storage area in a cell’ may mean: verifying the status of the cell after performing PAE (‘programming after erasing’), reading the data storage area current status, verifying the data storage area ‘Program’ state, or verifying the data storage area ‘Erase’ state. According to some embodiments of the present invention, the NVM cell array may be associated with a ‘virtual-ground’ (“VG”) architecture, a full VG array; sliced VG array, and/or with segmented VG architecture.

As part of the present disclosure, there may be provided a system for evaluating the status of a non-volatile memory (“NVM”) cell of interest that resides within an NVM cell array. According to some embodiments of the present disclosure, the system may comprise an ‘X’ address decoder (“X-DEC”) for driving a word line in the NVM cell array to select a cell of interest and for deactivating other word lines for deselecting other cells. The system may also comprise ‘Y’ address decoder (“Y-DEC”) for activating, when appropriate, selection gates in the NVM cell array to connect, or disconnect, the cell of interest to, or from, corresponding bit lines. The bit lines may be driven (for example, activated and deactivated) by a Y-multiplexer (“Y-MUX”) interoperating with the Y-DEC.

Leakage current in one or more cells that are connected to the bit line(s) of the cell of interest may be suppressed by causing the X-DEC to direct a suppressing voltage while the status of the data storage area is being evaluated. The NVM cell array may be structured as ‘two-bit-per-cell’ architecture. In this architecture, bit lines associated with an ‘evaluated’ data storage area may change roles to allow evaluating both data storage areas (for example, bits).

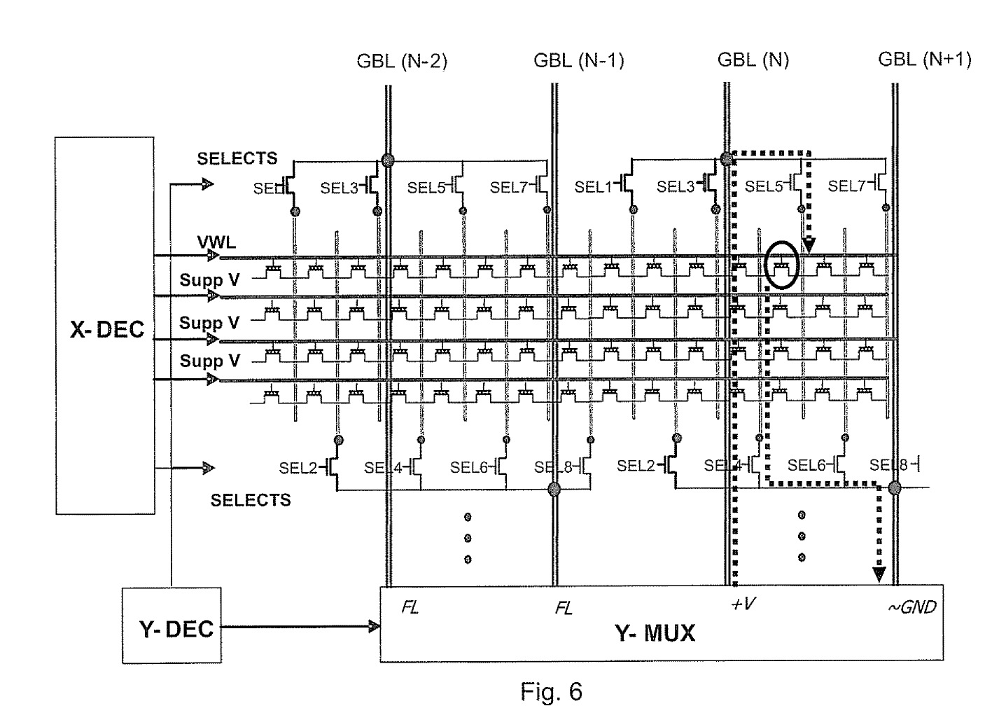

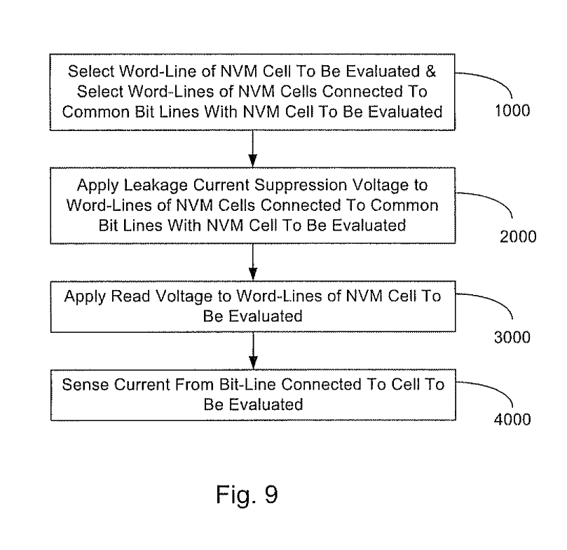

Turning now to FIG. 6, there is shown a diagram of an exemplary Non-Volatile Memory sensing circuit according to some embodiments, including dashed lines indicating a sensing current path and further including an indication of a suppression voltage being applied to the word-lines of cells whose leakage current may corrupt the sensing current. FIG. 6 may be described in conjunction with FIG. 9 which is a flow chart including the steps of an exemplary method of sensing a Non-Volatile Memory cell according to some embodiments. According to embodiments associated with FIG. 6, an NVM cell being sense/evaluated may be accessed by selecting the word-line and bit-lines (step 1000 in FIG. 9) associated with the cell (cell indicated with a circle in FIG. 6). The world-line associated with the cell to be evaluated may receive an activation voltage (for example, read word-line voltage) which attracts charge carriers to the channel of the cell (step 3000 in FIG. 9) Either substantially concurrently with, or prior to, applying the activation word-line voltage (step 3000 in FIG. 9), a suppression word-line voltage (Vsupp in FIG. 6) may be applied to the word-lines of a cell in proximity (for example, connected to the same bit-line) to the cell being evaluated (step 2000 in FIG. 9).

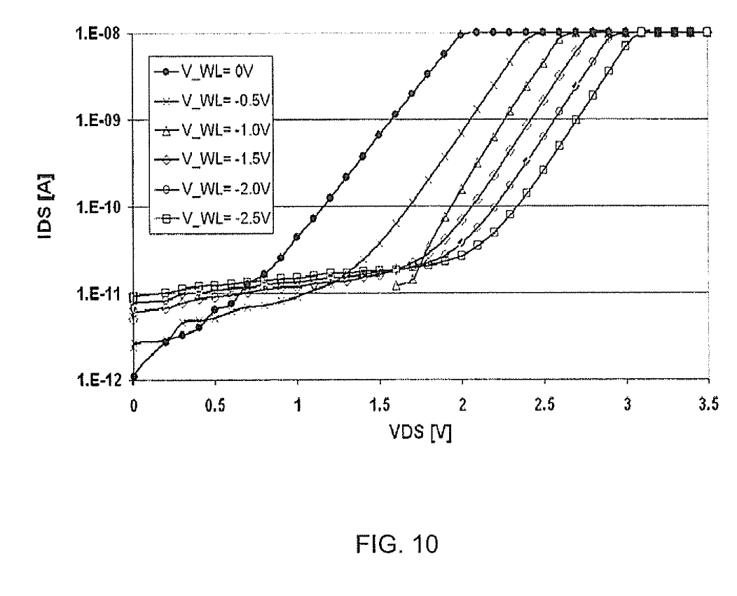

Reference is now made to FIG. 10 that shows the measured current-voltage characteristics of a leaky NVM cell. The different curves show a drain current (‘IDS’) vs. a Drain voltage (‘VDS’) for different Gate (for example, Word Line) voltages (V_WL). According to some embodiments, when a voltage of 0V is applied to a leaky NVM cell gate, then at standard read conditions (for example, VDS=2V) a current higher than 10 nA will flow through the cell. If tens or hundreds of such leaky cells are connected in parallel to an NVM cell that is being read, then these leaky cells may generate a current signal high enough (for example, higher than 1 uA) that will significantly affect the readout of the NVM cell being read. However, FIG. 10 shows that for all the curves that refer to negative V_WL, if a slightly negative gate voltage (V_WL) is applied to the leaky cell, the leakage current flowing through that cell may be reduced by a few orders of magnitude. Accordingly, the existence of such leaky cells connected in parallel to an NVM cell being read will not affect the readout of that NVM cell.

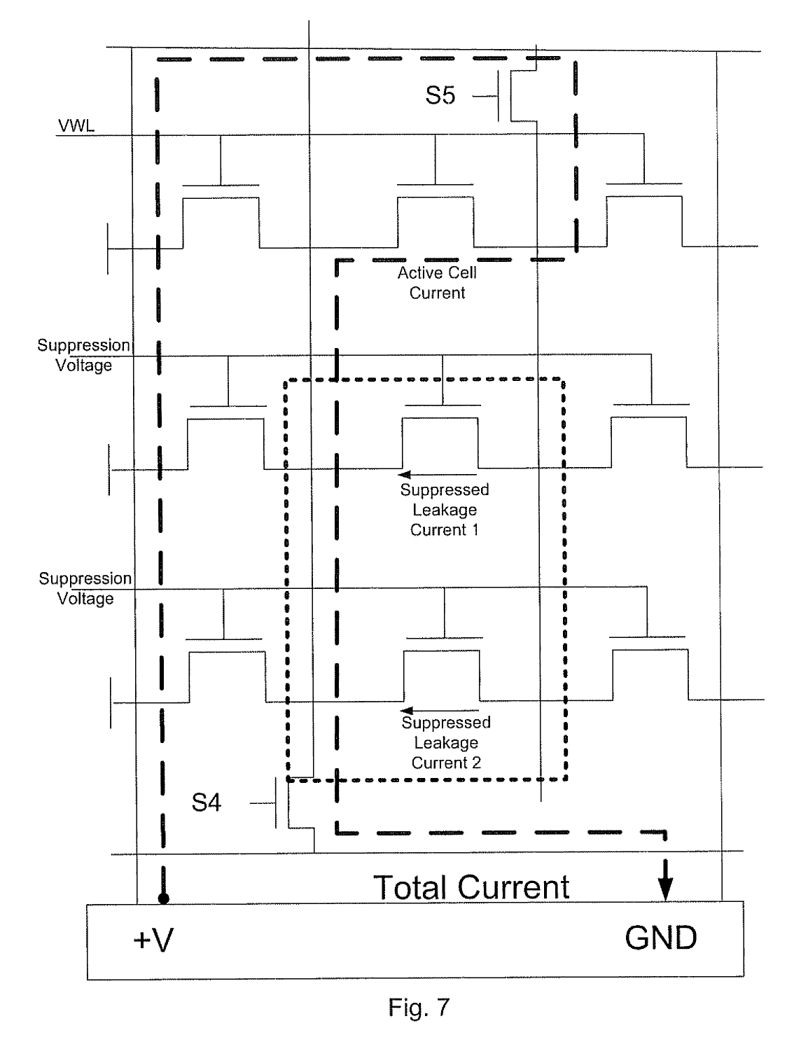

Turning now to FIG. 7, there is shown a close-up of the sensing and leakage current paths within the circuit shown in FIG. 6. As indicated in FIG. 7, the leakage current in cells receiving a suppression voltage have reduced leakage currents. Once leakage currents are suppressed, the relevant/active cell may be sense/evaluated (step 4000 in FIG. 9). Sensing may be performed by driving the bit-lines connected to the relevant cell or by any other method known today or to be devised in the future.

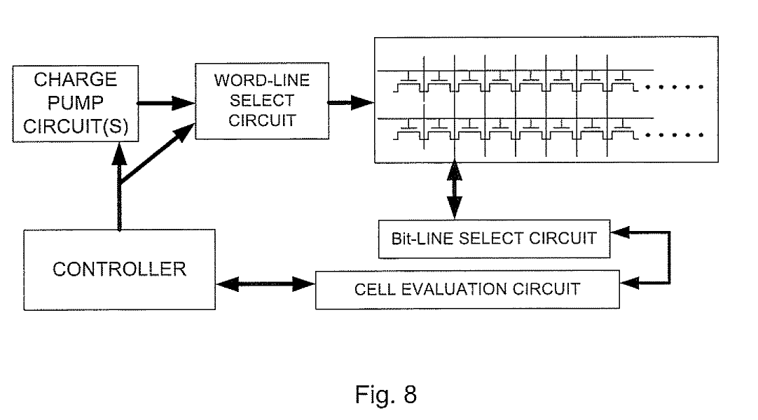

Turning now to FIG. 8, there is shown a block diagram of an exemplary Non-Volatile Memory circuit and device according to some embodiments. A controller or control circuit may signal a word-line select circuit (for example, X-DEC) to select a word-line associated with a cell to be evaluated and the word-lines of the cells whose leakage current could corrupt the sensing current (step 1000 in FIG. 9). The controller may signal a charge pump circuit to generate a suppression voltage to be applied to the word-lines of the cells not being evaluated and a read word-line voltage to be applied to the word-line of the cell to be evaluated. The controller may also signal a cell evaluation circuit to drive a sensing current through bit-lines connected to the cell to be sensed/evaluated.

While certain features of this disclosure have been illustrated and described herein, many modifications, substitutions, changes, and equivalents will now occur to those skilled in the art. It is, therefore, to be understood that the appended claims are intended to cover all such modifications and changes as fall within the true spirit of this disclosure.

What is claimed is:

1. A method of evaluating the status of a data storage area in a Non-Volatile Memory (“NVM”) Cell within a non-volatile memory array comprising:
suppressing leakage current in one or more NVM Cells of the array other than the cell being evaluated.

2. The method according to claim 1, wherein suppressing comprises applying a suppression voltage to a word-line of the one or more NVM cells whose leakage current is being suppressed.

3. The method according to claim 2, wherein the suppression voltage is applied to cells sharing a bit line with the cell being evaluated.

4. The method according to claim 2, wherein the suppression voltage is a negative voltage.

5. The method according to claim 1, wherein evaluating the status of a data storage area within an NVM cell is part of an operation selected from a group of operations consisting of a read operation, a program verify operation and an erase verify operation.

6. The method according to claim 1 wherein the array type is selected from a group of types consisting of a full virtual-ground array, a sliced virtual-ground array, and a segmented virtual-ground.

7. A Non-Volatile Memory device adapted to evaluate the status of a first non-volatile memory cell while applying a negative voltage to at least one second non-volatile memory cell.

8. The device according to claim 7, wherein said second non-volatile memory cell shares the same bit line with said first non-volatile memory cell.

9. A circuit for evaluating the status of a data storage area in a Non-Volatile Memory (“NVM”) Cell within a non-volatile memory array comprising:
a controller adapted to cause a suppression voltage to be applied to one or more NVM cells in proximity to the NVM cell whose data storage area is being evaluated.

10. The circuit according to claim 9, wherein the suppression voltage is generated by a charge pump.

11. The circuit according to claim 10, wherein the suppression voltage is applied to a word-line of the one or more NVM cells whose leakage current is being suppressed.

12. The circuit according to claim 9, further comprising a word-line select circuit, said word-line select circuit adapted to direct the suppression voltage to the word-lines of the one or more NVM cells whose leakage current is being suppressed.

13. The circuit according to claim 12, wherein the suppression voltage is applied to cells sharing a bit line with the cell being evaluated.

14. The circuit according to claim 9, wherein the suppression voltage is a negative voltage.

15. The circuit according to claim 9, wherein evaluating the status of a data storage area within an NVM cell is part of an operation selected from a group of operations consisting of a read operation, a program verify operation and an erase verify operation.

16. A Non-volatile memory device comprising:
an array of NVM cells;
a controller adapted to cause a suppression voltage to be applied to one or more NVM cells in proximity to an NVM cell whose data storage area is being evaluated;

17. The device according to claim 16, wherein the suppression voltage is generated by a charge pump.

18. The device according to claim 17, wherein said charge pump is adapted to produce the suppression voltage such that the suppression voltage is a voltage capable of inducing a sufficiently strong electric field in an NVM cell to substantially deplete charge carriers from a channel of the NVM cell.

19. The device according to claim 16, wherein the suppression voltage is applied to a word-line of the one or more NVM cells whose leakage current is being suppressed.

20. The device according to claim 16, further comprising a word-line select circuit, said word-line select circuit adapted to direct the suppression voltage to the word-lines of the one or more NVM cells whose leakage current is being suppressed.

21. The device according to claim 16, wherein the suppression voltage is a negative voltage.
